(19) United States
(12) Patent Application Publication
(10) Pub. No.: US 2022/0377905 A1
(43) Pub. Date: Nov. 24, 2022

(54) Method for Designing PCB Pads, Device and Medium

(71) Applicant: Inspur Suzhou Intelligent Technology Co., Ltd., Suzhou (CN)

(72) Inventor: Caikun Yang, Suzhou (CN)

(21) Appl. No.: 17/772,946

(22) PCT Filed: Jun. 28, 2020
(86) PCT No.: PCT/CN2020/098405

§ 371 Date: Apr. 28, 2022

(30) Foreign Application Priority Data
Oct. 31, 2019 (CN) 201911049653.8

(51) Int. Cl. H05K 3/00; G05B 19/18; H05K 1/11; H05K 3/42

(52) U.S. Cl. CPC H05K 3/0047; G05B 19/182; H05K 3/0005; H05K 1/116; H05K 3/423; G05B 2219/45035; H05K 2201/09827; H05K 2201/09481

(57) ABSTRACT

A method for designing PCB pads: using a drill bit of a first size to drill through a PCB from a first side; using a drill bit of a second size to back-drill a second side of the PCB so as to form a pyramid-shaped through hole; setting the connection means of a second layer and third layer of an inner layer of the PCB that comprises the pyramid-shaped through hole to full connection; and disposing a pad of a third size on a first layer of the inner layer, and disposing a pad of a fourth size on the last layer of the inner layer, wherein the fourth size is bigger than the third size, the fourth size is bigger than the second size, the second size is bigger than the first size, and the third size is bigger than the first size.

### CROSS REFERENCE TO RELATED APPLICATIONS

This application claims priority to Chinese Patent Application No. 201911049653.8, filed to the CNIPA on Oct. 31, 2019, and entitled “METHOD FOR DESIGNING PCB PADS, DEVICE AND MEDIUM”, the entire content of which is incorporated herein by reference.

### TECHNICAL FIELD

The present disclosure relates to the fields of PCBs, in particular to a method for designing PCB pads, a device and a readable medium.

### BACKGROUND

Problems such as poor soldering of a wave soldered device frequently occur in the process of wave soldering a PCB, such poor soldering is caused by various factors, and from the viewpoint of PCB design, poor soldering is mainly caused by unreasonable design of pads of the PCB to which the device is wave soldered, and thus, problems such as unfirm soldering, dummy soldering, and false soldering of the wave soldered device are caused due to insufficient tin on the bottom side of the device and insufficient tin creepage in a pin through hole during wave soldering.

In the design process of the pads of the PCB to which the device is wave soldered, the pad is generally designed according to the size of a pin of the device, the diameter of a through hole of the pad is the diameter of the pin of the device plus 0.2 to 0.4 mm, as shown in FIG. 1. The size of a pad on the surface is the diameter of the through hole plus 0.4 to 0.6 mm, as shown in FIG. 2. In the case that such a design of the pads of a PCB package is adopted, if poor soldering conditions such as superhigh or superlow preheating and soldering temperatures of the PCB and a slightly small climbing angle of the PCB occur, the poor soldering, such as problems including insufficient tin creepage and shriveled and incomplete solder joints, of the final wave soldered device may be caused in the wave soldering process.

### SUMMARY

In view of this, objectives of embodiments of the present disclosure are to provide a method for designing PCB pads, a device and a medium. By means of providing a pyramid-shaped through hole, the amount of tin creepage in the hole may be increased to the greatest extent, and top side continuous soldering caused by overflow of excessive soldering tin on a top side may be prevented, so that problems such as insufficient tin on a wave soldered device, dummy soldering, and false soldering may be prevented, and the current carrying capacity of a power source on an inner layer may also be increased.

Based on the above-mentioned objectives, in a first aspect of embodiments of the present disclosure, provided is a method for designing PCB pads, including the following steps: using a drill bit with a first size to drill through a PCB from a first side; using a drill bit with a second size to back-drill a second side of the PCB so as to form a pyramid-shaped through hole; setting the connection means of a second layer and third layer of an inner layer of the PCB that includes the pyramid-shaped through hole to full connection; and disposing a pad with a third size on a first layer of the inner layer, and disposing a pad with a fourth size on the last layer of the inner layer, wherein the fourth size is bigger than the third size, the fourth size is bigger than the second size, the second size is bigger than the first size, and the third size is bigger than the first size.

In some implementations, the using a drill bit with a first size to drill through a PCB from a first side includes: using the drill bit with the first size to drill through the PCB perpendicular to the first side of the PCB, wherein the first size is bigger than the size of a pin of a device to be soldered.

In some implementations, the using a drill bit with a second size to back-drill a second side of the PCB so as to form a pyramid-shaped through hole includes: using the drill bit with the second size to back-drill the second side of the PCB to a position of a half of the thickness of the PCB so as to form the pyramid-shaped through hole.

In some implementations, the using the drill bit with the second size to back-drill the second side of the PCB so as to form the pyramid-shaped through hole further includes: electroplating an interior of the pyramid-shaped through hole with copper.

In some implementations, the disposing a pad with a third size on a first layer of the inner layer further includes: judging whether the first layer of the inner layer of the PCB that includes the pyramid-shaped through hole can be fully connected; and setting the first layer to be in thermal relief connection in response to the determination that the first layer of the inner layer of the PCB that includes the pyramid-shaped through hole cannot be fully connected.

In another aspect of the embodiments of the present disclosure, further provided is a computer device including at least one processor; and a memory, wherein the memory stores a computer instruction capable of running on the processor, and the instruction is executed by the processor to implement the following steps: using a drill bit with a first size to drill through a PCB from a first side; using a drill bit with a second size to back-drill a second side of the PCB so as to form a pyramid-shaped through hole; setting the connection means of a second layer and third layer of an inner layer of the PCB that includes the pyramid-shaped through hole to full connection; and disposing a pad with a third size on a first layer of the inner layer, and disposing a pad with a fourth size on the last layer of the inner layer, wherein the fourth size is bigger than the third size, the fourth size is bigger than the second size, the second size is bigger than the first size, and the third size is bigger than the first size.

In some implementations, the using a drill bit with a first size to drill through a PCB from a first side includes: using the drill bit with the first size to drill through the PCB perpendicular to the first side of the PCB, wherein the first size is bigger than the size of a pin of a device to be soldered.

In some implementations, the using a drill bit with a second size to back-drill a second side of the PCB so as to form a pyramid-shaped through hole includes: using the drill bit with the second size to back-drill the second side of the PCB to a position of a half of the thickness of the PCB so as to form the pyramid-shaped through hole.

In some implementations, the using the drill bit with the second size to back-drill the second side of the PCB so as to form the pyramid-shaped through hole further includes: electroplating an interior of the pyramid-shaped through hole with copper.

In further aspect of the embodiments of the present disclosure, further provided is a computer readable storage medium storing a computer program used for implementing the steps of the above-mentioned method when being executed by a processor.

The present disclosure has the following beneficial technical effects: by means of providing a pyramid-shaped through hole, the amount of tin creepage in the hole may be increased to the greatest extent, and top side continuous soldering caused by overflow of excessive soldering tin on a top side may be prevented, so that problems such as insufficient tin on a wave soldered device, dummy soldering, and false soldering may be prevented, and the current carrying capacity of a power source on an inner layer may also be increased.

### BRIEF DESCRIPTION OF THE DRAWINGS

In order to describe the technical solutions in embodiments of the present disclosure or in the prior art more clearly, the accompanying drawings required for describing the embodiments or the prior art will be briefly introduced below. Apparently, the accompanying drawings in the following description show only some embodiments of the present disclosure, and a person of ordinary skill in the art may still derive other accompanying drawings from these accompanying drawings without creative efforts.

FIG. 1 is a sectional view of a PCB with a pad through hole in accordance with the prior art;

FIG. 2 is a top view of the PCB with the pad through hole in accordance with the prior art;

FIG. 3 is a schematic diagram of an embodiment of a method for designing PCB pads in accordance with the present disclosure;

FIG. 4 is a sectional view of a PCB with a pad through hole in accordance with the present disclosure;

FIG. 5 is a sectional view of a PCB with pads in accordance with the present disclosure;

FIG. 6 is a flowchart of an embodiment of a method for designing PCB pads in accordance with the present disclosure; and

FIG. 7 is a schematic diagram of a hardware structure of an embodiment of the method for designing the PCB pads in accordance with the present disclosure.

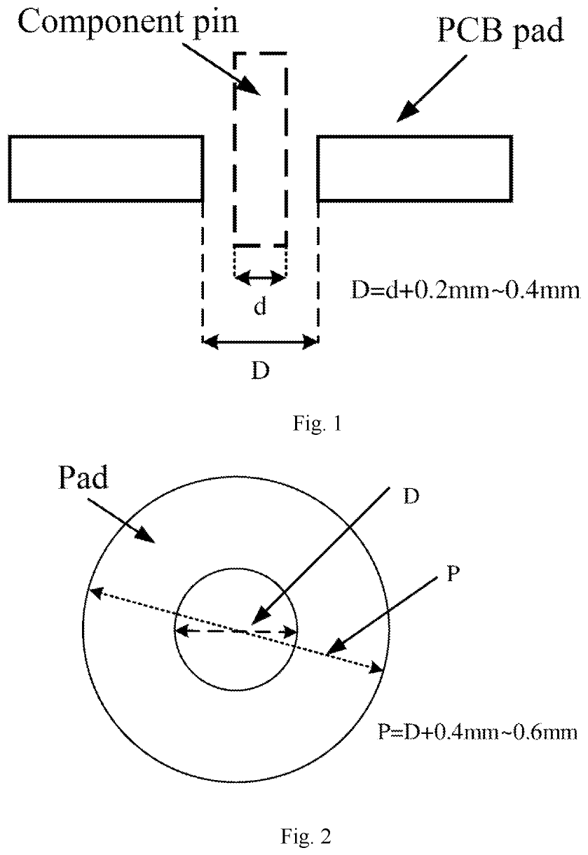

### DETAILED DESCRIPTION

In order to make objectives, technical solutions and advantages of the present disclosure clearer and more understandable, embodiments of the present disclosure will be further described in detail below in conjunction with specific embodiments and the accompanying drawings.

It should be noted that the expressions “first” and “second” used in the embodiments of the present disclosure are used to distinguish two different entities or parameters with the same names, and therefore, “first” and “second” are only for the purpose of facilitating expression, but should not be understood as limitations on the embodiments of the present disclosure, which will not be repeatedly described in the subsequent embodiments.

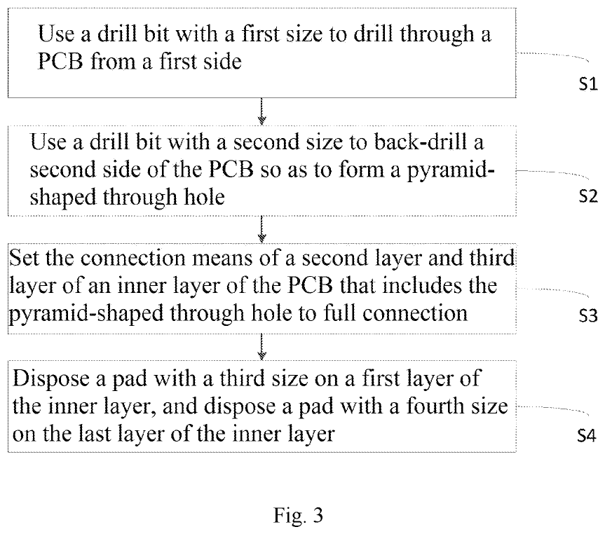

Based on the above-mentioned objectives, in a first aspect of embodiments of the present disclosure, provided is an embodiment of a method for designing PCB pads. FIG. 3 is a schematic diagram of an embodiment of a method for designing PCB pads in accordance with the present disclosure. As shown in FIG. 3, the embodiment of the present disclosure includes the following steps:

S1, using a drill bit with a first size to drill through a PCB from a first side,

S2, using a drill bit with a second size to back-drill a second side of the PCB so as to form a pyramid-shaped through hole;

S3, setting the connection means of a second layer and third layer of an inner layer of the PCB that includes the pyramid-shaped through hole to full connection; and

S4, disposing a pad with a third size on a first layer of the inner layer, and disposing a pad with a fourth size on the last layer of the inner layer.

Wherein the fourth size is bigger than the third size, the fourth size is bigger than the second size, the second size is bigger than the first size, and the third size is bigger than the first size.

The drill bit with the first size is used to drill through the PCB from the first side, and the drill bit with the second size is used to back-drill the second side of the PCB so as to form the pyramid-shaped through hole. The first size represents the size of the top side of the through hole, and the second size represents the size of the bottom side of the through hole. A pad through hole of the PCB package to which a device is wave soldered is designed to be pyramid-shaped, and in this embodiment, the first side is the top side of the PCB, and the second side is the bottom side of the PCB. Firstly, a drill bit with the size of the top side of the through hole is adopted to drill through the PCB, and then, a drill bit with the size of the bottom side of the through hole is adopted to back-drill the bottom side of the PCB, wherein the size of the top side of the through hole is smaller than the size of the bottom side of the through hole. This design means of the pad through hole has the advantages for wave soldering that the diameter of the through hole in the bottom side is increased, by which the tin creepage area of soldering tin entering the through hole may be increased, so that the amount of tin in the hole is increased; and the diameter of the through hole in the top side is reduced, by which the risk that excessive tin creeps in the through hole to overflow to the surface of the device may be reduced.

In some implementations, the using a drill bit with a first size to drill through a PCB from a first side includes: using the drill bit with the first size to drill through the PCB perpendicular to the first side of the PCB, wherein the first size is bigger than the size of a pin of a device to be soldered. For example, the diameter of the top side of the through hole may be set to be the diameter of the pin of the device plus 0.15 to 0.2 mm.

In some implementations, using a drill bit with a second size to back-drill a second side of the PCB so as to form a pyramid-shaped through hole includes: using the drill bit with the second size to back-drill the second side of the PCB to a position of a half of the thickness of the PCB so as to form the pyramid-shaped through hole, wherein the second size is bigger than the size of a pin of a device to be soldered. The diameter of the bottom side of the through hole may be set to be the diameter of the pin of the device plus 0.3 to 0.5 mm. In some implementations, using the drill bit with the second size to back-drill the second side of the PCB so as to form the pyramid-shaped through hole further includes: electroplating an interior of the pyramid-shaped through hole with copper.

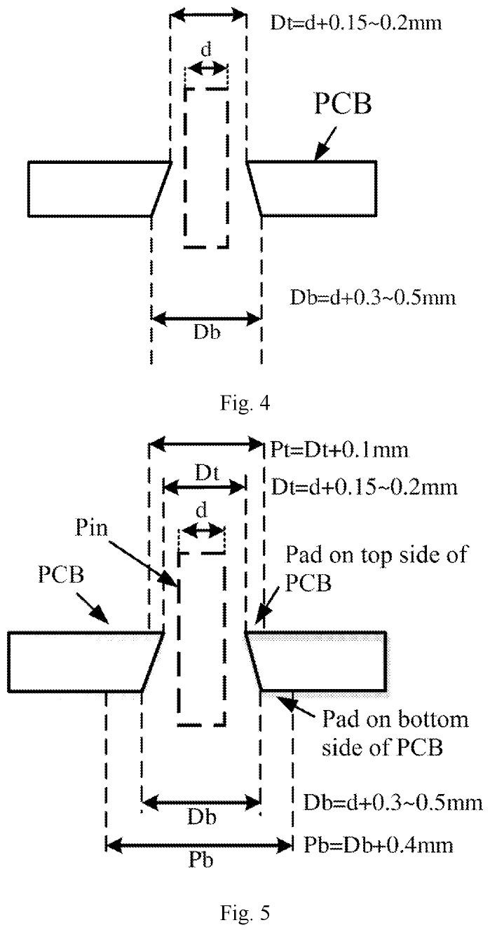

FIG. 4 is a sectional view of a PCB with a pad through hole in accordance with the present disclosure. As shown in FIG. 4, the size of a pin of a device to be soldered is d, the first size Dt=d+0.15−0.2 mm, the second size Db=d+0.3−0.5 mm, and it is obvious that the second size is bigger than the first size.

The connection means of the second layer and third layer of the inner layer of the PCB that includes the pyramid-shaped through hole is set to full connection. The connection means of plane layers of the pads on the inner layer is improved on the basis of the above-mentioned design of the pin through hole. Generally, the connection of the inner layer of the through hole is thermal relief connection under which soldering tin may radiate heat relatively slowly and the soldering tin may creep to the top side to overflow from the top side under the conditions of larger amount of tin in the through hole and overhigh tin soldering speed. Therefore, the connection means of the inner layer is required to be changed, the connection means of the second layer and third layer of the inner layer is changed to full connection, and other layers are still designed to be in thermal relief connection. By means of the design of the connection means of the pads on the inner layer, several layers on the top side may radiate heat as soon as possible under the condition of sufficient tin creepage to cool and lock the soldering tin, so that the phenomenon that excessive soldering tin overflows from the top side is avoided. Meanwhile, several layers on the bottom side radiate heat relatively slowly, and thus, sufficient tin creepage time is ensured. In addition, if the pin is a power pin, such a design means of the full connection of the several layers on the top side of the inner layer may increase the current carrying capacity and avoid insufficient current carrying capacity when a large current carrying capacity is required.

The pad with the third size is disposed on the first layer of the inner layer, and the pad with the fourth size is disposed on the last layer of the inner layer. In some implementations, the disposing the pad with the third size on the first layer of the inner layer further includes: judging whether the first layer of the inner layer of the PCB that includes the pyramid-shaped through hole can be fully connected; and setting the first layer to be in thermal relief connection in response to the determination that the first layer of the inner layer of the PCB that includes the pyramid-shaped through hole cannot be fully connected. Finally, the pads on the top and bottom sides are designed, the size of the pad on the top side is designed to be the diameter of the top side of the through hole plus 0.1 to 0.3 mm, preferably 0.2 mm, and the size of the pad on the bottom side is designed to be the diameter of the bottom side of the through hole plus 0.38 to 0.42 mm, preferably 0.4 mm.

FIG. 5 is a sectional view of a PCB with pads in accordance with the present disclosure. As shown in FIG. 5, the third size Pt=Dt+0.1 mm, and the fourth size Pb=Db+0.4 mm. By means of such a design means, the pad on the top side is shrunk, and thus, the phenomenon that excessive tin creeps in the hole to cause excessive tin be absorbed on the top side so as to result in the overflow of the tin from the top side may be reduced; and the pad on the bottom side is enlarged, by which the tin absorption area may be increased, so that rapider tin creepage in the hole may be achieved.

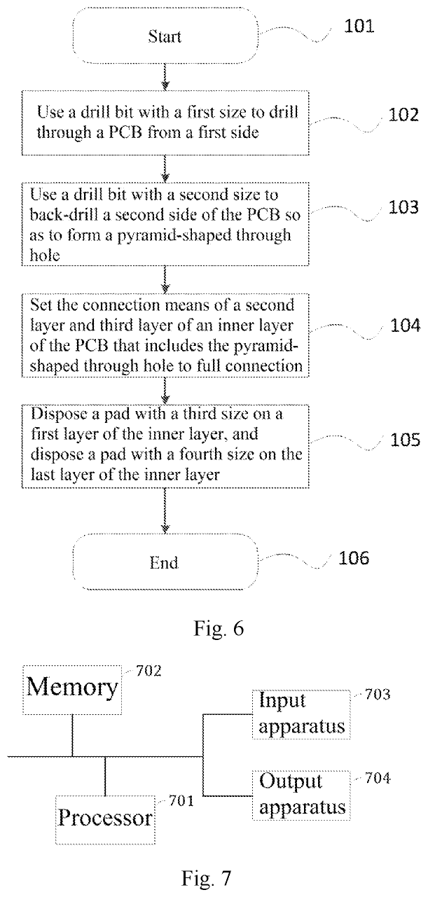

FIG. 6 is a flowchart of an embodiment of a method for designing PCB pads in accordance with the present disclosure. As shown in FIG. 6, start from a block 101 which represents start, then, proceed to a block 102 which represents using a drill bit with a first size to drill through a PCB from a first side; next, proceed to a block 103 which represents using a drill bit with a second size to back-drill a second side of the PCB so as to form a pyramid-shaped through hole; then, proceed to a block 104 which represents setting the connection means of a second layer and third layer of an inner layer of the PCB that includes the pyramid-shaped through hole to full connection; then, proceed to a block 105 which represents disposing a pad with a third size on a first layer of the inner layer, and disposing a pad with a fourth size on the last layer of the inner layer; and then, proceed to a block 106 which represents end.

It should be specially pointed out that all the steps in each of the above-mentioned embodiments of the method for designing the PCB pads may intersect, be replaced, be added and be deleted each other, so that these reasonable arrangement and combination transformations of the method for designing the PCB pads should also fall within the protection scope of the present disclosure, and the protection scope of the present disclosure should not be limited to the embodiments.

Based on the above-mentioned objectives, in a second aspect of the embodiments of the present disclosure, provided is a computer device including at least one processor; and a memory, wherein the memory stores a computer instruction capable of running on the processor, and the instruction is executed by the processor to implement the following steps: S1, using a drill bit with a first size to drill through a PCB from a first side; S2, using a drill bit with a second size to back-drill a second side of the PCB so as to form a pyramid-shaped through hole; S3, setting the connection means of a second layer and third layer of an inner layer of the PCB that includes the pyramid-shaped through hole to full connection; and S4, disposing a pad with a third size on a first layer of the inner layer, and disposing a pad with a fourth size on the last layer of the inner layer.

In some implementations, the using a drill bit with a first size to drill through a PCB from a first side includes: using the drill bit with the first size to drill through the PCB perpendicular to the first side of the PCB, wherein the first size is bigger than the size of a pin of a device to be soldered.

In some implementations, the using a drill bit with a second size to back-drill a second side of the PCB so as to form a pyramid-shaped through hole includes: using the drill bit with the second size to back-drill the second side of the PCB to a position of a half of the thickness of the PCB so as to form the pyramid-shaped through hole, wherein the second size is bigger than the size of a pin of a device to be soldered.

In some implementations, the using the drill bit with the second size to back-drill the second side of the PCB so as to form the pyramid-shaped through hole further includes: electroplating an interior of the pyramid-shaped through hole with copper.

In some implementations, the disposing a pad with a third size on a first layer of the inner layer further includes: judging whether the first layer of the inner layer of the PCB that includes the pyramid-shaped through hole can be fully connected; and setting the first layer to be in thermal relief connection in response to the determination that the first layer of the inner layer of the PCB that includes the pyramid-shaped through hole cannot be fully connected.

FIG. 7 is a schematic diagram of a hardware structure of an embodiment of the method for designing the PCB pads in accordance with the present disclosure.

With an apparatus as shown in FIG. 7 as an example, the apparatus includes one processor 701 and one memory 702 and may further include an input apparatus 703 and an output apparatus 704.

The processor 701, the memory 702, the input apparatus 703 and the output apparatus 704 may be connected by a bus or in other means, and FIG. 7 is described with the connection by a bus as an example.

As a non-volatile computer readable storage medium, the memory 702 may be used for storing a non-volatile software program and a non-volatile computer executable program and module such as a program instruction/module corresponding to the method for designing the PCB pads in the embodiments of this application. The processor 701 executes various function applications and data processing of a server by running the non-volatile software program, instruction and module stored in the memory 702, namely, implementing the method for designing the PCB pads in the above-mentioned method embodiments.

The memory 702 may include a program storage area and a data storage area, wherein the program storage area may store an operating system and an application program required for at least one function; and the data storage area may store data and the like created according to the use of the method for designing the PCB pads. In addition, the memory 702 may include a high-speed random access memory and may further include a non-volatile memory such as at least one magnetic disk memory device, a flash memory device or other non-volatile solid-state memory devices. In some embodiments, the memory 702 optionally includes memories remotely disposed relative to the processor 701, and these remote memories may be connected to a local module through a network. Examples of the above-mentioned network include, but are not limited to an Internet, an Intranet, a local area network, a mobile communication network and combinations thereof.

The input apparatus 703 may receive input information such as a user name and a password. The output apparatus 704 may include a display device such as a display screen.

One or more program instructions/modules corresponding to the method for designing the PCB pads are stored in the memory 702 and are used to execute the method for designing the PCB pads in any one of the above-mentioned method embodiments when being executed by the processor 701.

Any one of the embodiments of the computer device for implementing the above-mentioned method for designing the PCB pads may achieve the same or similar effects as any one of the above-mentioned corresponding method embodiments.

The present disclosure further provides a computer readable storage medium storing a computer program used for implementing the above-mentioned method when being executed by a processor.

Finally, it should be noted that, those of ordinary skill in the art can understand that the implementation of all or parts of processes in the methods in the above-mentioned embodiments may be completed by relevant hardware instructed by the computer program, the program of the method for designing the PCB pads may be stored in a computer readable storage medium, and the program may include the processes in all the above-mentioned embodiments of the method when being executed. A storage medium of the program may be a magnetic disk, an optical disk, a read-only memory (ROM) or a random access memory (RAM) and the like. The above-mentioned embodiments of the computer program may achieve the same or similar effects as any one of the above-mentioned corresponding method embodiments.

In addition, the method disclosed in accordance with the embodiments of the present disclosure may be further implemented as a computer program executed by a processor, and the computer program may be stored in a computer readable storage medium. When the computer program is executed by a processor, the above-mentioned functions defined in the method disclosed in accordance with the embodiments of the present disclosure are executed.

In addition, the above-mentioned method steps and system units may also be implemented by a controller and a computer readable storage medium for storing a computer program enabling the controller to implement the above-mentioned steps or functions of the units.

In addition, it should be understood that the computer readable storage medium (such as a memory) described herein may be a volatile memory or a non-volatile memory or include both of the volatile memory and the non-volatile memory. As an example rather than a limitation, the non-volatile memory may include a read-only memory (ROM), a programmable ROM (PROM), an electrically programmable ROM (EPROM), an electrically erasable and programmable ROM (EEPROM) or a flash memory. The volatile memory may include a random access memory (RAM), the RAM may serve as an external high-speed cache memory. As an example rather than a limitation, the RAM may be achieved in various forms such as a synchronous RAM (SRAM), a dynamic RAM (DRAM), a synchronous DRAM (SDRAM), a double-data-rate SDRAM (DDR SDRAM), an enhanced SDRAM (ESDRAM), a synchronization link DRAM (SLDRAM) and a direct Rambus RAM (DRRAM). The memory devices in the disclosed aspects are intended to include, but not limited to these and other appropriate types of memories.

It should be further understood by those skilled in the art that various exemplary logic blocks, modules, circuits and algorithm steps described in combination with the embodiments disclosed herein may be implemented as electronic hardware, computer software or a combination of both. In order to describe the interchangeability of the hardware and the software clearly, general description has been performed according to functions of various schematic components, blocks, modules, circuits and steps. Whether these functions are implemented as hardware or software depends upon specific applications and design constraints applied to the overall system. Those skilled in the art may achieve the functions in various ways for each specific application, however, such implementation decisions should not be interpreted as departing from the scope disclosed by the embodiments of the present disclosure.

Various exemplary logic blocks, modules and circuits described in combination with the disclosure described herein may be implemented or executed by the following components designed to implement the functions described herein: a general-purpose processor, a digital signal processor (DSP), an application specific integrated circuit (ASIC), a field-programmable gate array (FPGA) or other programmable logic devices, a discrete gate or transistor logic device and a discrete hardware component or any combinations of these components. The general-purpose processor may be a microprocessor, however, alternatively, the processor may be any traditional processor, controller, microcontroller or state machine. The processor may also be implemented as a combination of computing devices, such as a combination of a DSP and a microcontroller, a plurality of microprocessors, a combination of one or more of the microprocessors and the DSP and/or any other such configurations.

The steps of the method or algorithm described in combination with the disclosure described herein may be directly included in hardware, a software module executed by a processor or a combination of both. The software module may reside in an RAM, a flash memory, an ROM, an EPROM, an EEPROM, a register, a hard disk, a mobile disk, a CD-ROM or a storage medium in any other forms known in the art. An exemplary storage medium is coupled to a processor, so that the processor may read information from the storage medium or write the information into the storage medium. In an alternative, the storage medium may be integrated with the processor. The processor and the storage medium may reside in an ASIC. The ASIC may reside in a user terminal. In an alternative, the processor and the storage medium may be used as discrete components to reside in the user terminal.

In one or more exemplary designs, functions may be achieved in hardware, software, firmware or any combinations thereof. If the functions are achieved in the software, the functions may be used as one or more instructions or codes to be stored in a computer readable medium or transmitted via the computer readable medium. The computer readable medium includes a computer storage medium and a communication medium, and the communication medium includes any medium beneficial to transmission of a computer program from one position to another position. The storage medium may be any available medium which may be accessed by a general-purpose or application-specific computer. As an example rather than a limitation, the computer readable medium may include an RAM, an ROM, an EEPROM, a CD-ROM or other optical disk storage devices, magnetic disk storage devices or other magnetic storage devices, or any other media used for carrying or storing program codes in forms of instructions or data structures and accessed by a general-purpose or application-specific computer or a general-purpose or application-specific processor. In addition, any connection may be appropriately called as a computer readable medium. For example, if a coaxial cable, an optical fiber cable, a double-stranded cable, a digital subscriber line (DSL) or wireless technologies such as infrared, radio and microwave technologies are used to transmit software from a website, a server or other remote sources, the above-mentioned coaxial cable, optical fiber cable, double-stranded cable, DSL or wireless technologies such as infrared, radio and microwave technologies fall within the definition of the medium. For example, the magnetic disk and the optical disk used herein include a compact disk (CD), a laser disk, an optical disk, a digital video disk (DVD), a floppy disk and a blue-ray disk, wherein the magnetic disk generally magnetically reproduce data, and the optical disk optically reproduce data by means of laser. The combinations of the above-mentioned contents should also be included in the scope of the computer readable medium.

The above descriptions are exemplary embodiments disclosed by the present disclosure. However, it should be noted that various changes and modification may be made without departing from the scope disclosed in the embodiments of the present disclosure and defined in the claims. According to the method in the embodiments disclosed herein, functions, steps and/or actions in the claims do not need to be performed in any specific order. In addition, although elements disclosed by the embodiments of the present disclosure may be described or claimed in a singular form, the elements, unless explicitly limited to the singular, may also be construed as being plural.

It should be understood that the singular form “one” used herein is intended to further include a plural form unless an exceptional case is clearly supported in the context. It should be further understood that “and/or” used herein refers to any one and all of possible combinations of one or more items which are listed relevantly.

The serial numbers of the embodiments of the present disclosure are disclosed for a descriptive purpose only, rather than representing that the embodiments are good or bad.

Those of ordinary skill in the art can understand that all or parts of steps in the above-mentioned embodiments may be completed by means of hardware or relevant hardware instructed by a program which may be stored in a computer readable storage medium. The above-mentioned storage medium may be a read-only memory, a magnetic disk or an optical disk and the like.

Those of ordinary skill in the art should understand that the discussion of any of the above-mentioned embodiments is only exemplary, but is not intended to imply that the scope (including the claims) disclosed in the embodiments of the present disclosure is limited to these examples. Technical features in the above-mentioned embodiments or different embodiments may also be combined under the thought of the embodiments of the present disclosure, and there are many other changes in different aspects of the above-mentioned embodiments of the present disclosure, for simplicity, they are not provided in detail. Therefore, any omissions, modifications, equivalent replacements, improvements and the like made within the spirit and principle of the embodiments of the present disclosure shall fall within the protection scope of the embodiments of the present disclosure.

1. A method for designing PCB pads, comprising the following steps:
using a drill bit with a first size to drill through a PCB from a first side;
using a drill bit with a second size to back-drill a second side of the PCB so as to form a pyramid-shaped through hole;
setting the connection means of a second layer and third layer of an inner layer of the PCB that comprises the pyramid-shaped through hole to full connection; and
disposing a pad with a third size on a first layer of the inner layer, and disposing a pad with a fourth size on the last layer of the inner layer,
wherein the fourth size is bigger than the third size, the fourth size is bigger than the second size, the second size is bigger than the first size, and the third size is bigger than the first size.

2. The method according to claim 1, wherein the using a drill bit with a first size to drill through a PCB from a first side comprises:
using the drill bit with the first size to drill through the PCB perpendicular to the first side of the PCB, wherein the first size is bigger than the size of a pin of a device to be soldered.

3. The method according to claim 2, wherein the using a drill bit with a second size to back-drill a second side of the PCB so as to form a pyramid-shaped through hole comprises:
using the drill bit with the second size to back-drill the second side of the PCB to a position of a half of the thickness of the PCB so as to form the pyramid-shaped through hole.

4. The method according to claim 3, wherein the using the drill bit with the second size to back-drill the second side of the PCB so as to form the pyramid-shaped through hole further comprises:
electroplating an interior of the pyramid-shaped through hole with copper.

5. The method according to claim 1, wherein the disposing a pad with a third size on a first layer of the inner layer further comprises:
judging whether the first layer of the inner layer of the PCB that comprises the pyramid-shaped through hole can be fully connected; and
setting the first layer to be in thermal relief connection in response to the determination that the first layer of the inner layer of the PCB that comprises the pyramid-shaped through hole cannot be fully connected.

6. A computer device, comprising:
at least one processor; and
a memory, wherein the memory stores a computer instruction capable of running on the processor, and the instruction, when being executed by the processor, implements the following steps:
using a drill bit with a first size to drill through a PCB from a first side;
using a drill bit with a second size to back-drill a second side of the PCB so as to form a pyramid-shaped through hole;
setting the connection means of a second layer and third layer of an inner layer of the PCB that comprises the pyramid-shaped through hole to full connection; and
disposing a pad with a third size on a first layer of the inner layer, and disposing a pad with a fourth size on the last layer of the inner layer,
wherein the fourth size is bigger than the third size, the fourth size is bigger than the second size, the second size is bigger than the first size, and the third size is bigger than the first size.

7. The computer device according to claim 6, wherein the using a drill bit with a first size to drill through a PCB from a first side comprises:
using the drill bit with the first size to drill through the PCB perpendicular to the first side of the PCB, wherein the first size is bigger than the size of a pin of a device to be soldered.

8. The computer device according to claim 7, wherein the using a drill bit with a second size to back-drill a second side of the PCB so as to form a pyramid-shaped through hole comprises:
using the drill bit with the second size to back-drill the second side of the PCB to a position of a half of the thickness of the PCB so as to form the pyramid-shaped through hole.

9. The computer device according to claim 8, wherein the using the drill bit with the second size to back-drill the second side of the PCB so as to form the pyramid-shaped through hole further comprises:
electroplating an interior of the pyramid-shaped through hole with copper.

10. A computer readable storage medium storing a computer program, wherein the steps of the method according to claim 1 are implemented when the computer program is executed by a processor.

11. A computer readable storage medium storing a computer program, wherein the steps of the method according to claim 2 are implemented when the computer program is executed by a processor.

12. A computer readable storage medium storing a computer program, wherein the steps of the method according to claim 3 are implemented when the computer program is executed by a processor.

13. A computer readable storage medium storing a computer program, wherein the steps of the method according to claim 4 are implemented when the computer program is executed by a processor.

14. A computer readable storage medium storing a computer program, wherein the steps of the method according to claim 5 are implemented when the computer program is executed by a processor.
